(19) United States
(12) Patent Application Publication
(10) Pub. No.: US 2008/0210166 A1
(43) Pub. Date: Sep. 4, 2008

(54) Plasma enhanced chemical vapor desposition device having multiple sub-electrodes

(75) Inventor: Shuo-Ting Yan, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 12/069,805

(22) Filed: Feb. 12, 2008

(30) Foreign Application Priority Data
Feb. 12, 2007 (TW) 96104973

(51) Int. Cl. C23C 16/505

(52) U.S. Cl. 118/723 E

(57) ABSTRACT

An exemplary PECVD device includes a first electrode (21), a second electrode (22) parallel to the first electrode, and a radio frequency (RF) circuit (23) providing energy for the two electrodes. The first electrode includes at least two separated sub-electrodes (211, 212). The RF circuit includes an RF power supply source (230) and at least two variable resistors (231, 232). The RF power supply source is connected to the at least two sub-electrodes via the at least two variable resistors respectively. The PECVD device can deposit a uniform thin film.

### FIELD OF THE INVENTION

The present invention relates to plasma enhanced chemical vapor deposition (PECVD) devices, and particularly to a PECVD device which includes an anode electrode having multiple sub-electrodes.

### GENERAL BACKGROUND

Generally, thin film deposition includes two types: physical vapor deposition (PVD) and chemical vapor deposition (CVD). PVD does not contain any chemical reaction, and mainly includes an evaporation method and a sputtering method. CVD is to form a thin film on a substrate through gaseous chemical reaction, and generally includes atmospheric pressure CVD (APCVD), low pressure CVD (LPCVD), and plasma enhanced CVD (PECVD). PECVD uses plasma as activating energy to promote the chemical reaction, thus a high temperature is required. The plasma is a mixture matter consisting of ions, electrons, and neutral particles. PECVD is now well developed and widely used.

Referring to FIG. 5, a typical PECVD device includes a chamber 11, a first electrode 12, a second electrode 13, and a radio frequency (RF) circuit 14. The chamber 11 includes a gas supply pipe 111 and an exhausting pipe 112. The first electrode 12 and the second electrode 13 is disposed in the chamber 11. The first electrode 12 and the second electrode 13 are plate-shaped, and are parallel to each other. The RF circuit 14 is disposed outside the chamber 11, and is connected between the first electrode 12 and the second electrode 13. The RF circuit 14 is configured to provide RF electric power.

Reaction gases are introduced into the chamber 11 through the gas supply pipe 111. Most of the reaction gases are converted into plasma consisting of ions, electrons, and neutral particles by the RF electric power formed between the first and second electrodes 12, 13. The reaction gases are excited by the plasma, and react with each other. Resultant of the chemical reaction is deposited on a substrate (not shown) disposed on the second electrode 13, thus a thin film is formed on the substrate. Waste gases are exhausted through the exhausting pipe 112.

The uniformity of the thin film is essentially determined by the uniformity of a consistency of the plasma. However, the plasma is apt to cluster because of its natural electric characteristic, thus the consistency of the plasma is generally non-uniform. In addition, the consistency of the plasma can be affected by conditions such as a temperature, a pressure, and a flow speed of the reaction gases. Therefore, a thickness of the deposited thin film formed by the PECVD device is liable to be unsatisfactory. What's more, with the trend of the substrate becoming larger, the uniformity of the thickness of the deposited thin film becomes worse.

What is needed, therefore, is a PECVD device that can overcome the above-described deficiencies.

### SUMMARY

In one preferred embodiment, a PECVD device includes a first electrode, a second electrode parallel to the first electrode, and a radio frequency (RF) circuit providing energy for the two electrodes. The first electrode includes at least two separated sub-electrodes. The RF circuit includes an RF power supply source and at least two variable resistors. The RF power supply source is connected to the at least two sub-electrodes via the at least two variable resistor respectively.

Other novel features and advantages of the present PECVD device will become more apparent from the following detailed description when taken in conjunction with the accompanying drawings.

### BRIEF DESCRIPTION OF THE DRAWINGS

FIG. 1 is a schematic, side view of a PECVD device according to a first embodiment of the present invention, an anode electrode of the PECVD device including three sub-electrodes.

FIG. 2 is a schematic view showing arrangement of the three sub-electrodes of FIG. 1.

FIG. 3 is similar to FIG. 2, but showing arrangement of sub-electrodes of an anode electrode of a PECVD device according to a second embodiment of the present invention.

FIG. 4 is similar to FIG. 2, but showing arrangement of sub-electrodes of an anode electrode of a PECVD device according to a third embodiment of the present invention.

FIG. 5 is a schematic, side cross-sectional view of a conventional PECVD device.

### DETAILED DESCRIPTION OF PREFERRED EMBODIMENTS

Reference will now be made to the drawing figures to describe various embodiments of the present invention in detail.

Referring to FIG. 1, a PECVD device according to a first embodiment of the present invention is shown. The PECVD device includes a first electrode 21, a second electrode 22, a radio frequency (RF) circuit 23, and a chamber 24. The chamber 24 is made from aluminum or glass, and includes a gas supply pipe 241 and an exhausting pipe 242. The first electrode 21 and the second electrode 22 are disposed parallel to each other, and are accommodated within the chamber 24. The first electrode 21 serves as an anode electrode, and the second electrode 22 serves as a cathode electrode and further servers as a supporter for supporting a glass substrate (not shown). The first electrode 21 and the second electrode 22 are made from aluminium (Al).

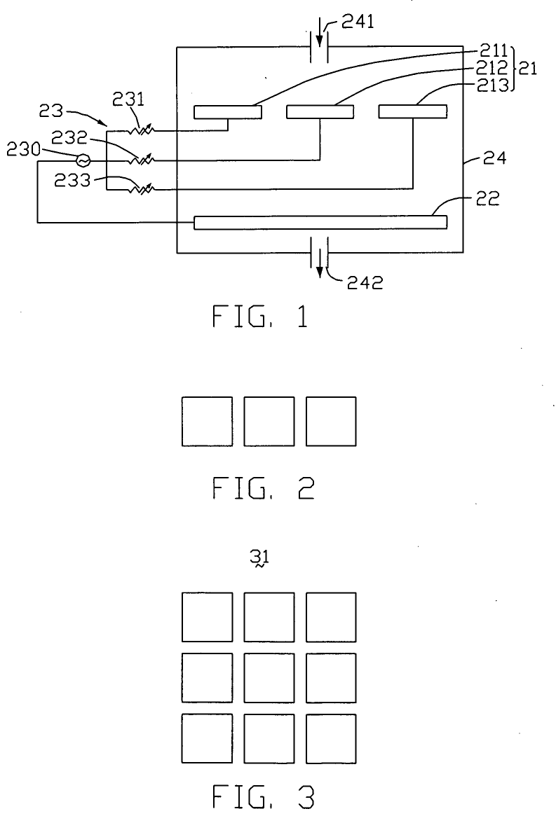

Referring to FIG. 2, the first electrode 21 includes three separated sub-electrodes 211, 212, 213. The three sub-electrodes 211, 212, 213 are in a same plane. That is, the sub-electrodes 211, 212, 213 have the same predetermined distance from the second electrode 22. The sub-electrodes 211, 212, 213 each have a rectangle shape. Two adjacent sub-electrodes are separated by a gap of 0.5 centimeter.

The RF circuit 23 is disposed outside the chamber 24, and includes an RF power supply source 230 and three variable resistors 231, 232, 233. One end of the RF power supply source 230 is connected to the second electrode 22, and the other end of the RF power supply source 230 is connected to the three sub-electrodes 211, 212, 213 via the three variable resistors 231, 232, 233 respectively. The RF circuit 23 has a working frequency of 13.56 MHz.

An example of a prescribed thin film which can be formed with the aid of the PECVD device is an amorphous silicon film (a-Si film). SiH₄ and H₂ gases are normally used as reaction gases in the formation of the amorphous silicon film. When the PECVD device is used to produce thin films on the substrate, a thin film for test is deposited. A consistency of the plasma can be calculated by measuring thicknesses of different regions of the test-needed thin film. The variable resistors 231, 232, 233 are adjusted such that electric fields are made uniform corresponding to each of the sub-electrodes 211, 212, 213. Thus, the consistency of the plasma becomes uniform and balanced. Then thin films can be deposited on the substrate uniformly.

Unlike the conventional PECVD device, because the first electrode 21 of the present PECVD device includes three separated sub-electrodes 211, 212, 213, and each sub-electrode is connected to the power supply source 230 via the corresponding variable resistor, the consistency of the plasma of different regions corresponding to the sub-electrodes 211, 212, 213 can be adjusted respectively by adjusting the three variable resistors 231, 232, 233. Therefore, even other conditions, such as a temperature and a pressure, are not uniform, a uniform consistency of the plasma is still acquired. Thus, a uniform thin film can be formed by using the PECVD device. In addition, because a consistency of the plasma corresponding to any one of sub-electrodes 211, 212, 213 can be adjusted independently by adjusting the variable resistors 231, 232, 233, if a prescribed thin film with different thicknesses in different regions is desired, it can be easily deposited through only one deposition process employing the PECVD device by adjusting the variable resistors 231, 232, 233 accordingly.

Referring to FIG. 3, a PECVD device according to a second embodiment of the present invention is similar to the PECVD device of the first embodiment. However, a first electrode 31 of the PECVD device includes nine separated sub-electrodes (not labeled) arranged in a 9-lattice matrix. Any two adjacent sub-electrodes are separated by a gap of 0.5 centimeter. Each sub-electrode is connected to a power supply source via a corresponding variable resistor. The PECVD device has similar advantages with the PECVD device of the first embodiment.

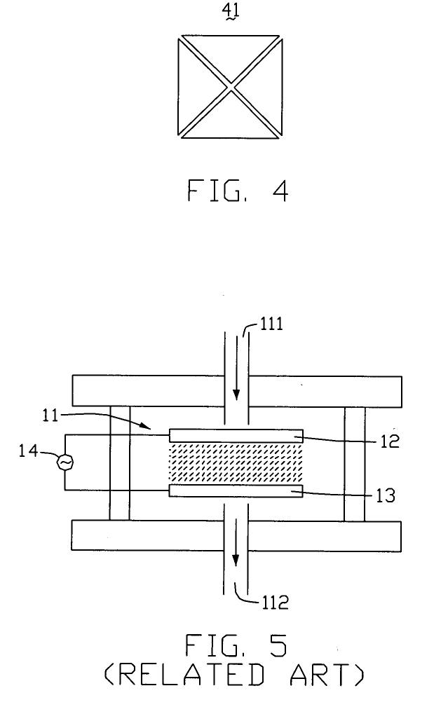

In further and/or alternative embodiments, any sub-electrode can have a triangle shape, or any other suitable shape. What's more, the number of the sub-electrodes can be two, four, or more. Referring to FIG. 4, a PECVD device according to a third embodiment of the present invention is similar to the PECVD device of the first embodiment. However, a first electrode 41 of the PECVD device includes four separated sub-electrodes (not labeled) arranged in a matrix. Each sub-electrode has a triangle shape, and any two adjacent sub-electrodes are separated by a gap of 0.5 centimeter.

It is to be understood, however, that even though numerous characteristics and advantages of the present embodiments have been set out in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A plasma enhanced chemical vapor deposition (PECVD) device, comprising:
a first electrode comprising at least two separated sub-electrodes;
a second electrode parallel to the first electrode; and
a radio frequency (RF) circuit configured to provide energy for the first and second electrodes, the RF circuit comprising an RF power supply source and at least two variable resistors, the RF power supply source connected to the at least two sub-electrodes via the at least two variable resistors respectively.

2. The PECVD device as claimed in claim 1, wherein the second electrode has a rectangle shape.

3. The PECVD device as claimed in claim 1, wherein each sub-electrode has a rectangle shape.

4. The PECVD device as claimed in claim 1, wherein each sub-electrode has a triangle shape.

5. The PECVD device as claimed in claim 3, wherein the at least two sub-electrodes are in the same plane.

6. The PECVD device as claimed in claim 5, wherein the at least two sub-electrodes are separated by a gap of 0.5 centimeter.

7. The PECVD device as claimed in claim 1, wherein the first electrode comprises nine sub-electrodes.

8. The PECVD device as claimed in claim 7, wherein the nine sub-electrodes are arranged in a 9-lattice matrix.

9. The PECVD device as claimed in claim 1, wherein the at least two electrodes are made from aluminium.

10. The PECVD device as claimed in claim 1, wherein the RF power supply source has a frequency of 13.56 MHz.

11. The PECVD device as claimed in claim 1, wherein the second electrode is configured for supporting a substrate.

12. The PECVD device as claimed in claim 1, wherein the second electrode serves as a cathode electrode.

13. The PECVD device as claimed in claim 1, wherein the first electrode serves as an anode electrode.

14. The PECVD device as claimed in claim 1, further comprising a chamber, the two electrodes being disposed in the chamber, the RF circuit being disposed outside the chamber.

15. The PECVD device as claimed in claim 14, wherein the chamber is made from glass or aluminium.

16. A plasma enhanced chemical vapor deposition (PECVD) device, comprising:
a first electrode comprising at least two separated sub-electrodes;
a second electrode parallel to the first electrode; and
a radio frequency (RF) circuit comprising an RF power supply source and at least two variable resistors, the RF power supply source configured to provide energy for the at least two sub-electrodes via the at least two variable resistors respectively.

17. The PECVD device as claimed in claim 17, further comprising a chamber, the two electrodes being disposed in the chamber, the RF circuit being disposed outside the chamber.

18. The PECVD device as claimed in claim 17, wherein each sub-electrode has a rectangle shape.

19. The PECVD device as claimed in claim 19, wherein the at least two sub-electrodes are in a same plane, and are separated by a gap of 0.5 centimeter.

20. A plasma enhanced chemical vapor deposition (PECVD) device, comprising:
at least two regions, energy being provided to the at least two regions by a power supply source via at least two controllers respectively, so that consistencies of plasma in the at least two regions being controlled respectively.
